(19) United States
(12) Patent Application Publication
(10) Pub. No.: US 2026/0254435 A1
(43) Pub. Date: Aug. 27, 2026

(54) ELASTIC WAVE DEVICE, COMMUNICATION APPARATUS, AND MANUFACTURING METHOD

(71) Applicant: KYOCERA CORPORATION, Kyoto-shi, Kyoto (JP)

(72) Inventors: Yosuke NISHIOKA, Kyoto-shi (JP); Masaki NAMBU, Kyoto-shi (JP); Takashi KATO, Kyoto-shi (JP); Soichiro NOZOE, Kyoto-shi (JP)

(73) Assignee: KYOCERA CORPORATION, Kyoto-shi, Kyoto (JP)

(21) Appl. No.: 18/995,461

(22) PCT Filed: Jul. 21, 2023
(86) PCT No.: PCT/JP2023/026753

§ 371 Date: Jan. 16, 2025

(30) Foreign Application Priority Data
Jul. 21, 2022 (JP) 2022-116621

(51) Int. Cl. H03H 9/13; H03H 3/02; H03H 9/02; H03H 9/17

(52) U.S. Cl. CPC H03H 9/132; H03H 3/02; H03H 9/02149; H03H 9/02228; H03H 9/175; H03H 9/176

(57) ABSTRACT

Since an IDT electrode is fine, power durability against migration needs to improve. An elastic wave device includes a piezoelectric-body layer, an electrode provided on the piezoelectric-body layer, and a cover covering at least a part of a side surface of the electrode and containing an element constituting the piezoelectric-body layer other than oxygen and nitrogen.

### TECHNICAL FIELD

The present disclosure relates to an elastic wave device.

### BACKGROUND OF INVENTION

In an elastic wave device, an IDT electrode made of an aluminum film is formed on a piezoelectric substrate.

### CITATION LIST

### Patent Literature

Patent Document 1: JP 2003-078384 A

### SUMMARY

According to an aspect of the present disclosure, an elastic wave device includes: a piezoelectric-body layer; an electrode provided on the piezoelectric-body layer; and a cover covering at least a part of a side surface of the electrode. The cover contains an element constituting the piezoelectric-body layer other than oxygen and nitrogen.

According to another aspect of the present disclosure, a manufacturing method includes: forming a piezoelectric-body layer; forming an electrode provided on the piezoelectric-body layer; and performing dry etching on the piezoelectric-body layer and the electrode.

### BRIEF DESCRIPTION OF THE DRAWINGS

FIG. 1 is a schematic view illustrating a cross-sectional structure of an elastic wave device according to a first embodiment.

FIG. 2 is a view of elastic wave devices according to a comparative example and the first embodiment, which are arranged side-by-side for comparison.

FIG. 3 is a view of the elastic wave device illustrated in FIG. 1 in which a protective film is formed.

FIG. 4 is an example illustrating a cross-sectional structure of the elastic wave device according to the first embodiment.

FIG. 5 is a photo obtained by enlarging a part of FIG. 4.

FIG. 6 is a graph showing the composition amount of tantalum on a specific line segment in FIG. 5.

FIG. 7 shows a result of comparison of power durability between a case where dry etching is performed and a case where dry etching is not performed.

FIG. 8 is a schematic view illustrating a cross-sectional structure of an elastic wave device according to a second embodiment.

FIG. 9 is a diagram illustrating an example of a schematic configuration of a communication apparatus according to a third embodiment.

FIG. 10 is a schematic view illustrating a cross-sectional structure of an elastic wave device.

### DESCRIPTION OF EMBODIMENTS

There has been a problem with low power durability against electromigration due to a fine IDT electrode. In addition, when a step of forming a cover covering a side surface of the IDT electrode is added in order to improve the power durability against electromigration, the manufacturing process needs a plurality of additional steps. This leads to a problem in that the manufacturing cost increases.

### First Embodiment

### Plate Wave

The elastic wave device excites, for example, a plate wave. Alternatively, the elastic wave device may excite a bulk wave. The plate wave is classified into a Lamb wave whose vibration plane is perpendicular to a plate surface and an SH wave whose vibration plane is parallel to a plate surface. The Lamb wave is classified into an S mode that is a symmetric mode and an A mode that is an antisymmetric mode. An A1 mode corresponds to a first-order antisymmetric mode. Although an elastic wave device using the A1 mode Lamb wave will be described in the present embodiment, the type of wave is not limited thereto. For example, an elastic wave device may use the bulk wave in a thickness shear mode. Among various waves, the plate wave has a significant change in resonance characteristics when the thickness of a piezoelectric-body layer 3, which will be described below, changes. The bulk wave also has a significant change in resonance characteristics when the thickness of the piezoelectric-body layer 3, which will be described below, changes.

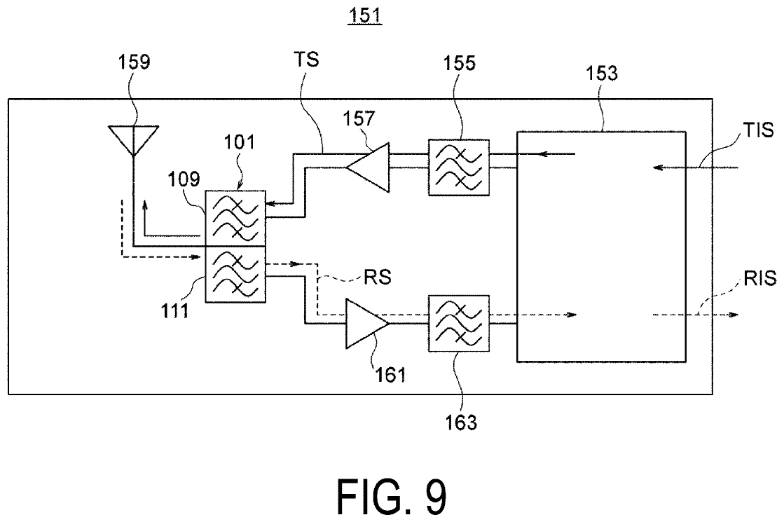

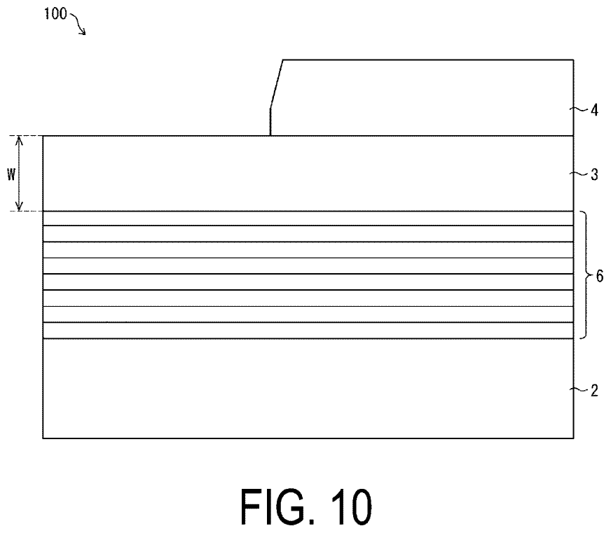

An example of a cross-sectional structure of the elastic wave device will be described. FIG. 9 is a schematic view illustrating a cross-sectional structure of an elastic wave device 100. The elastic wave device 100 is formed by overlapping a support substrate 2, a multilayer film 6, the piezoelectric-body layer 3, and an electrode 4 in this order.

The support substrate 2 supports the piezoelectric-body layer 3 and the electrode 4. The support substrate 2 may be made of silicon, or various materials such as sapphire and glass may be used.

The multilayer film 6 is an acoustic reflective film in which many low acoustic impedance layers 6a and high acoustic impedance layers 6b are alternately stacked. In FIG. 9, four low acoustic impedance layers 6a and four high acoustic impedance layers 6b are alternately stacked. Therefore, in the multilayer film 6, a Lamb wave propagating from above the elastic wave device 100 is reflected off an interface between the low acoustic impedance layer 6a and the high acoustic impedance layer 6b. The low acoustic impedance layer 6a may contain SiO₂. The high acoustic impedance layer 6b may contain at least one selected from the group consisting of HfO₂, Ta₂O₅, and ZrO₂, for example contains HfO₂. The multilayer film 6 may be omitted.

The piezoelectric-body layer 3 is formed relatively thin. A thickness W of the piezoelectric-body layer 3 may be equal to or less than one wavelength of a plate wave excited by the electrode 4. The one wavelength is determined by a pitch of the electrodes 4 to be described below. The piezoelectric-body layer 3 is made of lithium tantalate, lithium niobate, or crystal. The piezoelectric-body layer 3 is not limited to these materials, and various piezoelectric materials may be used. In the following description, the piezoelectric-body layer 3 will be described as being made of lithium tantalate.

The electrode 4 has a comb-shaped interdigital transducer (IDT) electrode, that is, many electrode fingers are formed. The piezoelectric-body layer 3 is exposed in a portion where the electrode 4 is not formed. The wavelength of the plate wave excited by the piezoelectric-body layer 3 is determined by the pitch of the IDT electrodes. The electrode 4 is made of aluminum, copper, or an alloy thereof.

The piezoelectric-body layer 3 is also configured such that a plate wave is excited in the piezoelectric-body layer 3 by applying an alternating current to the electrode 4.

### Configuration of Comparative Example

In the elastic wave device 100 according to the comparative example, as illustrated in FIG. 9, the surface of the piezoelectric-body layer 3 is substantially aligned with the interface between the piezoelectric-body layer 3 and the electrode 4. That is, the electrode 4 is formed on the piezoelectric-body layer 3, and etching or other method is not performed thereafter.

### Outline of Method for Adjusting Frequency Characteristics

In the elastic wave device 100 of the comparative example, the thickness of the piezoelectric-body layer 3 and/or the electrode 4 varies depending on the position of the support substrate 2. The support substrate 2 is, for example, a silicon wafer. Therefore, the elastic wave device 100 has different frequency characteristics depending on the position of the support substrate 2.

In order to adjust the frequency characteristics of the elastic wave device 100, the thicknesses of the piezoelectric-body layer 3 and the electrode 4 can be adjusted by etching or other method.

### Outline of Elastic Wave Device 1

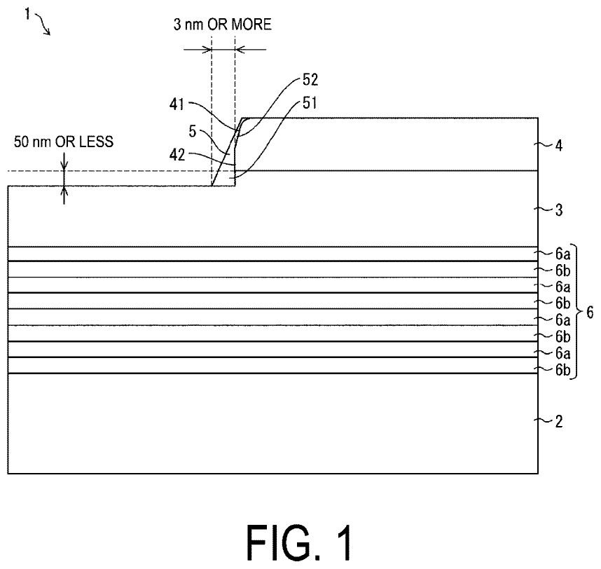

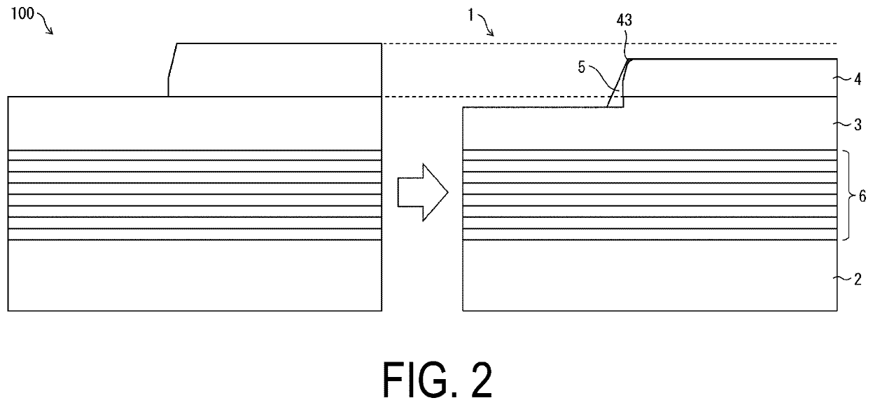

In an elastic wave device 1 according to the first embodiment, dry etching is performed to obtain a different thickness for each element or each portion of the element of the elastic wave device based on the thickness measured in advance. FIG. 1 is a schematic view illustrating a cross-sectional structure of the elastic wave device 1 according to the first embodiment. FIG. 2 is a view of the elastic wave device 100 according to the comparative example and the elastic wave device 1 according to the first embodiment, which are arranged side-by-side for comparison.

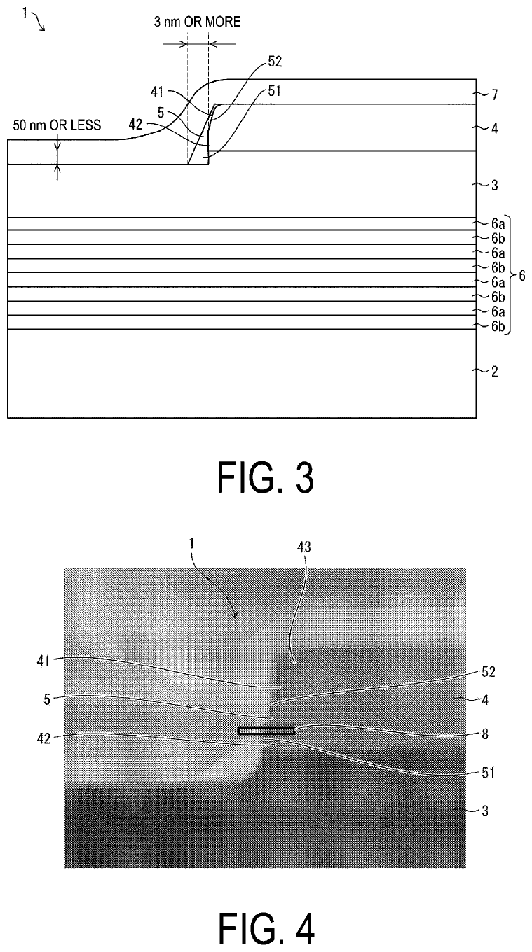

As illustrated in FIG. 2, in the elastic wave device 1, the piezoelectric-body layer 3 and the electrode 4 are thinner than those in the elastic wave device 100. Therefore, the elastic wave device 1 is adjusted so as to obtain desired frequency characteristics, and has improved frequency characteristics. FIG. 3 is an example illustrating a cross-sectional structure of the elastic wave device 1 according to the first embodiment. In FIG. 3, a scanning electron microscope (SEM) was used as an imaging method.

In particular, on the surface of the piezoelectric-body layer 3 and on the interface between the electrode 4 and the piezoelectric-body layer 3 where the electrode 4 is located thereon, the region where the surface of the piezoelectric-body layer 3 is exposed is thinner. The difference between the thicknesses is equal to or less than 50 nm. That is, the thickness of the piezoelectric-body layer 3 in a region of the electrode 4 is greater than the thickness of the piezoelectric-body layer 3 in a region where the surface thereof is exposed. The difference in thickness between the region of the electrode 4 and the region where the surface of the piezoelectric-body layer 3 is exposed is equal to or less than 50 nm.

As illustrated in FIG. 2 and can be seen from reference numeral 43, an edge of an end portion of the electrode 4 is removed and beveled by dry etching. Thus, an effect of reducing stress migration due to vibration of the electrode 4 can be obtained.

### Formation of Cover 5

The elastic wave device 1 includes a cover 5 covering at least a part of the side surface of the electrode 4. The cover 5 is not present in the elastic wave device 100. The support substrate 2 supports the piezoelectric-body layer 3, the electrode 4, and the cover 5.

The thickest portion of the cover 5 has a thickness equal to or more than 3 nm. The cover 5 includes a first portion 51, and a second portion that is located on the upper side of the electrode 4 relative to the first portion 51 and is thinner than the first portion. That is, the cover 5 does not have a uniform thickness, and the cover 5 has different thicknesses between the first portion 51 and the second portion 52. The cover 5 may become thinner toward the upper side of the electrode 4.

The side surface of the electrode 4 includes a first surface 41 that is not perpendicular to the surface of the piezoelectric-body layer 3. The first surface is located on the upper side of the electrode 4. The cover 5 is also in contact with the first surface.

Further, the side surface of the electrode 4 includes a second surface 42 in the vicinity of the surface of the piezoelectric-body layer 3. The second surface 42 is nearly perpendicular to the surface of the piezoelectric-body layer 3 compared to the first surface 41. The first surface and the second surface are continuous. The cover is also in contact with the second surface 42.

The second portion 52 is included in the first surface 41, and the first portion 51 is included in the second surface 42. That is, the angle formed between the direction perpendicular to the surface of the piezoelectric-body layer 3 and the second surface 42 is smaller than the angle formed between the direction perpendicular to the surface of the piezoelectric-body layer 3 and the first surface 41. Therefore, on the second surface 42, the thickness of the cover 5 is likely to increase.

Since the first surface 41 is inclined with respect to the surface of the piezoelectric-body layer 3, a contact area between the electrode 4 and the cover 5 is increased. As a result, formation of hillocks (protrusions) on the surface of the electrode 4 can be reduced, and an effect of improving power durability against electromigration can be obtained. Since the second surface 42 is nearly perpendicular to the surface of the piezoelectric-body layer 3, the deposition amount of the cover 5 increases. Therefore, when a protective film covering the piezoelectric-body layer 3 and the electrode 4 is formed, the coverage performance of the protective film in the vicinity of the second surface 42 is improved, and an effect of reducing electrolytic corrosion is obtained.

FIG. 3 is a view of the elastic wave device 1 illustrated in FIG. 1 in which a protective film 7 is formed. The protective film 7 covers the piezoelectric-body layer 3 and at least a part of the electrode 4. Specifically, the protective film 7 covers the lower side of the electrode 4, that is, a portion of the electrode 4 close to the piezoelectric-body layer 3 via the first portion 51. Example of materials of the protective film 7 may include various materials such as SiO₂, SiN, SiON, AlN, ZrO₂, Ta₂O₅, ZnO, Al₂O₃, and HfO₂, for example, SiO₂, SiN, AlN, or Ta₂O₅ may be used.

### Composition of Cover 5

As illustrated in FIG. 3, there is a high possibility that the compositions of the piezoelectric-body layer 3 and the cover 5 are similar to each other in the SEM image. In view of this, the portion removed by the dry etching is considered to have been redeposited. That is, the electrode 4 is considered to have been covered by the cover 5.

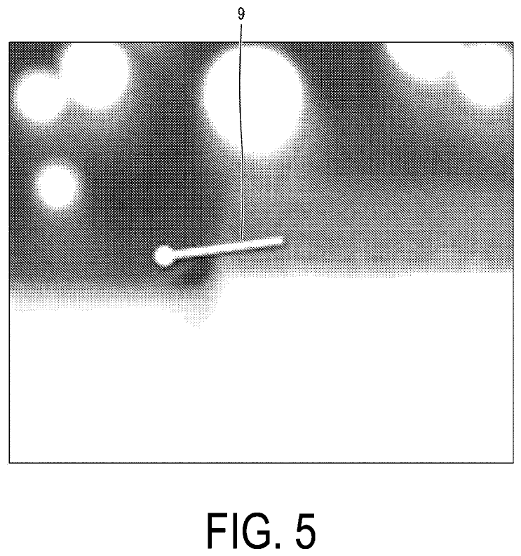

FIG. 4 is an enlarged view of a part (reference numeral 8) of the photograph of FIG. 3 in order to analyze the composition of the cover 5 in detail. FIG. 5 shows the measurement of the composition amount of tantalum on the line segment indicated by reference numeral 9 in FIG. 4.

As shown in the lower part of FIG. 5, the measurement value of the constituent amount of tantalum increases in a section from 60 nm to 80 nm. That is, it is understood that the tantalum element is contained in the section of the cover 5. Actually, in view of this section and the upper part of FIG. 5 corresponding to this section, in which the change in shades may indicate the change in composition, the tantalum element is considered to have been measured.

The electrode 4 is considered to have been covered by the composition of the piezoelectric-body layer 3. When the piezoelectric-body layer 3 is made of lithium tantalate, the element constituting the cover 5 may include lithium or tantalum. When the piezoelectric-body layer 3 is made of lithium niobate, the element constituting the cover 5 may include lithium or niobium. When the piezoelectric-body layer 3 is made of crystal, the element constituting the cover 5 may include silicon. When the piezoelectric-body layer 3 is made of another kind of piezoelectric material, the cover 5 may contain various elements contained in the piezoelectric material. The various elements are, for example, metal elements. That is, the cover 5 contains an element constituting the piezoelectric-body layer 3 other than oxygen and nitrogen. In this description, it is sufficient that the cover 5 contains an element other than oxygen and nitrogen among the elements constituting the piezoelectric-body layer 3, however, it is still allowable that the cover 5 may contain oxygen and nitrogen.

When the piezoelectric-body layer 3 is made of lithium tantalate, the cover 5 may be made of lithium tantalate, that is, tantalum oxide. When the piezoelectric-body layer 3 is made of lithium niobate, the cover 5 may be made of lithium niobate, that is, niobium oxide.

### Improvement in Power Durability

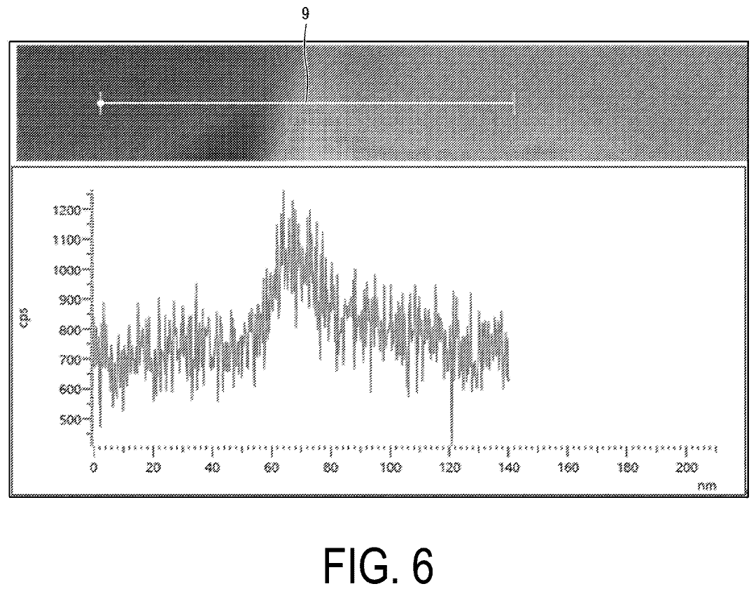

FIG. 6 shows a result of comparison of power durability between a case where dry etching is performed and a case where dry etching is not performed. That is, in the case where dry etching was performed, the elastic wave device 1 was tested, and in the case where dry etching was not performed, the elastic wave device 100 was tested. Two types of tests were performed including measurement of the breakdown power of the element of the elastic wave device 1 or 100, and measurement of the migration power at which electromigration starts to occur in the electrode 4.

As shown in FIG. 6, performing the dry etching increases the breakdown power and the migration power. That is, it is understood that the power durability is improved by dry etching.

This is considered to be an effect of the coverage of the electrode 4 by the cover 5. That is, since the electrode 4 is covered with tantalum, niobium, or other element, which has a higher density than aluminum constituting the electrode 4, electromigration is less likely to occur.

Further, the coverage of the electrode 4 by the cover 5 also increases the insulation distance. Furthermore, the coverage of the electrode 4 by the cover 5 reduces the possibility of hillock formation.

The difference between the inclination angles of the first surface 41 and the second surface 42 with respect to the piezoelectric-body layer 3 can increase the deposition amount of the cover 5 or the area of the electrode 4 in contact with the cover 5. As a result, electromigration is less likely to occur.

### Manufacturing Method

The elastic wave device 1 is manufactured by the following steps. First, the piezoelectric-body layer 3 is formed on the support substrate 2. Further, an aluminum film is formed on the piezoelectric-body layer 3, and the aluminum film is etched using a photoresist mask to form the electrode 4.

Thereafter, the thicknesses of the piezoelectric-body layer 3 and the electrode 4 are measured by various thickness measuring methods. The reason for this is to calculate the extent of etching in order to obtain the elastic wave device 1 in which the frequency characteristics are adjusted to a desired value.

An etching amount for obtaining desired frequency characteristics is calculated from each of the measured thicknesses. The piezoelectric-body layer 3 and the electrode 4 are dry-etched by the etching amount different for each element to obtain the elastic wave device 1. The cover 5 is formed by causing the material separated from the piezoelectric-body layer 3 by the dry etching to adhere to at least a part of the side surface of the electrode 4. That is, by performing the dry etching, the thickness of the piezoelectric-body layer 3 is adjusted in order to obtain desired frequency characteristics, and at the same time, the cover 5 that improves the power durability can be formed. Thus, the process of obtaining desired frequency characteristics is originally a necessary minimum step. Therefore, the manufacturing process does not need a plurality of additional steps.

### Second Embodiment

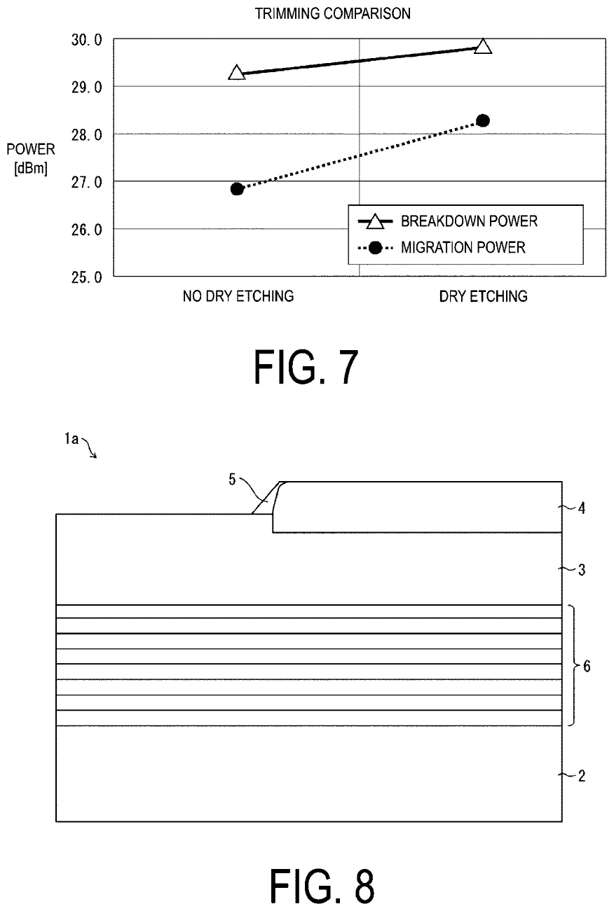

FIG. 7 is a schematic view illustrating a cross-sectional structure of an elastic wave device 1a according to a second embodiment. The elastic wave device 1a is different from the elastic wave device 1 in that a portion of the electrode 4 is embedded in the piezoelectric-body layer 3. Then, dry etching is performed in the same and/or similar manner to the first embodiment, and as a result, the cover 5 is formed.

Therefore, in addition to by the cover 5, the embedded portion of the electrode 4 is covered by the piezoelectric-body layer 3, that is, the electrode 4 is covered by tantalum, niobium, or other element, which has a higher density than aluminum. As a result, electromigration is less likely to occur in the electrode 4 and the power durability is improved.

### Third Embodiment

FIG. 8 is a diagram illustrating an example of the schematic configuration of a communication apparatus 151 according to a third embodiment. The communication apparatus 151 is an application example of the elastic wave device according to an aspect of the present disclosure. The communication apparatus 151 performs wireless communication using radio waves. The communication apparatus 151 may include one duplexer 101 serving as a transmission filter 109 and another duplexer 101 serving as a reception filter 111. Each of the two duplexers 101 may include the elastic wave device according to an aspect of the present disclosure. The elastic wave device may be the elastic wave device 1 or the elastic wave device 1a. Thus, the communication apparatus 151 may include the elastic wave device according to an aspect of the present disclosure.

In the communication apparatus 151, a radio frequency-integrated circuit (RF-IC) 153 may convert, into a transmission signal TS, a transmission information signal TIS including information to be transmitted, by modulating the transmission information signal TIS and increasing the frequency thereof. The modulation and the frequency increase may be a conversion into a high-frequency signal having a carrier frequency. A band-pass filter 155 may remove, from the TS, unnecessary components other than a transmission passband. Subsequently, the TS from which unnecessary components have been removed may be amplified by an amplifier 157 and sent to the transmission filter 109.

The transmission filter 109 may remove, from the received transmission signal TS, unnecessary components other than the transmission passband. The transmission filter 109 may output the TS from which unnecessary components have been removed, to an antenna 159 via an antenna terminal. As the antenna terminal, for example, the above-described TCin may be used. The antenna 159 may convert the TS, which is an electrical signal input to the antenna 159, into a radio wave as a radio signal, and transmit the radio wave to the outside of the communication apparatus 151.

The antenna 159 may receive a radio wave from the outside, convert the radio wave into a received signal RS that is an electrical signal, and send the RS to the reception filter 111 via the antenna terminal. The reception filter 111 may remove, from the received RS, unnecessary components other than a reception passband. The reception filter 111 may output the received signal RS from which unnecessary components have been removed, to an amplifier 161. The amplifier 161 may amplify the output RS. A band-pass filter 163 may remove, from the amplified RS, unnecessary components other than a reception passband. The RF-IC 153 may convert, into a reception information signal RIS, the RS from which unnecessary components have been removed, by decreasing the frequency of the RS and demodulating the RS.

The TIS and RIS may be low-frequency signals (baseband signals) including appropriate information. For example, the TIS and RIS may be analog audio signals or digitized audio signals. The passband of the radio signal may be appropriately set or may conform to various known standards.

### CONCLUSION

An elastic wave device according to a first aspect of the present disclosure includes a piezoelectric-body layer, an electrode provided on the piezoelectric-body layer, and a cover covering at least a part of a side surface of the electrode and containing an element constituting the piezoelectric-body layer other than oxygen and nitrogen.

According to the above-described configuration, the likelihood of electromigration of the electrode can be reduced by the cover, and thus the power durability of the elastic wave device is improved.

In an elastic wave device according to a second aspect of the present disclosure, in the first aspect, the piezoelectric-body layer may contain lithium tantalate, and the element may be lithium or tantalum.

In an elastic wave device according to a third aspect of the present disclosure, in the first aspect, the piezoelectric-body layer may contain lithium niobate, and the element may be lithium or niobium.

In an elastic wave device according to a fourth aspect of the present disclosure, in the first aspect, the piezoelectric-body layer may contain crystal, and the element may be silicon.

According to the above-described configuration, the cover partially contains the elements constituting the piezoelectric-body layer. Therefore, the constituent elements of the piezoelectric-body layer redeposited by dry etching cover the electrode.

In an elastic wave device according to a fifth aspect of the present disclosure, in the first or second aspect, the piezoelectric-body layer may be made of lithium tantalate, and the cover may contain tantalum oxide.

In an elastic wave device according to a sixth aspect of the present disclosure, in the first or third aspect, the piezoelectric-body layer may be made of lithium niobate and the cover may contain niobium oxide.

According to the above-described configuration, the cover contains a compound of elements constituting the piezoelectric-body layer. Therefore, the compound related to the piezoelectric-body layer redeposited by dry etching covers the electrode.

In an elastic wave device according to a seventh aspect of the present disclosure, in any one of the first to sixth aspects, a density of the cover may be larger than a density of the electrode.

According to the above-described configuration, the electrode is covered by the cover made of an element having a higher density than that of the electrode, so that electromigration of the electrode can be avoided.

In an elastic wave device according to an eighth aspect of the present disclosure, in any one of the first to seventh aspects, a thickest portion of the cover may have a thickness equal to or more than 3 nm.

According to the above-described configuration, the thickness of the cover can be set equal to or more than 3 nm, and the electrode can be covered with the cover having a sufficient thickness. Thus, power durability of the elastic wave device can be improved.

In an elastic wave device according to a ninth aspect of the present disclosure, in any one of the first to eighth aspects, the cover may include a first portion, and a second portion that is located on an upper side of the electrode relative to the first portion and is thinner than the first portion.

According to the above-described configuration, the thickness of the cover can be increased toward the piezoelectric-body layer.

An elastic wave device according to a tenth aspect of the present disclosure, in any one of the first to ninth aspects, may further include a protective film covering the piezoelectric-body layer and at least a part of the electrode, and the protective film may cover a portion of the electrode near the piezoelectric-body layer via a first portion.

According to the above-described configuration, the coverage performance of the protective film in the vicinity of the lower side of the electrode is improved, and the effect of reducing the electrolytic corrosion is obtained.

In an elastic wave device according to an eleventh aspect of the present disclosure, in any one of the first to tenth aspects, a side surface of the electrode may include a first surface that is not perpendicular to a surface of the piezoelectric-body layer, and the cover may be in contact with the first surface.

According to the above-described configuration, the side surface of the electrode can include the first surface that is not perpendicular to the surface of the piezoelectric-body layer. Therefore, a contact area between the electrode and the cover can be increased.

In an elastic wave device according to a twelfth aspect of the present disclosure, in the eleventh aspect, the side surface of the electrode may further include a second surface that is located near the surface of the piezoelectric-body layer and is continuous with a first surface, an angle formed between a direction perpendicular to the surface of the piezoelectric-body layer and the second surface may be smaller than an angle formed between the direction perpendicular to the surface of the piezoelectric-body layer and the first surface, and the cover may be in contact with the second surface.

According to the above-described configuration, the side surface of the electrode can include the second surface that is nearly perpendicular to the surface of the piezoelectric-body layer compared to the first surface in the vicinity of the surface of the piezoelectric-body layer. Therefore, a large deposition amount of the cover on the second surface can be obtained.

In an elastic wave device according to a thirteenth aspect of the present disclosure, in any one of the first to twelfth aspects, a thickness of the piezoelectric-body layer in a region of the electrode may be larger than a thickness of the piezoelectric-body layer in a region where a surface of the piezoelectric-body layer is exposed.

According to the above-described configuration, the thickness of the piezoelectric-body layer can be reduced in the region where the surface of the piezoelectric-body layer is exposed compared to the region overlapping the electrode. That is, the piezoelectric-body layer can be subjected to dry etching together with the electrode, and the processing is easy.

In an elastic wave device according to a fourteenth aspect of the present disclosure, in any one of the first to thirteenth aspects, a difference in thickness between the region of the electrode and the region where the surface of the piezoelectric-body layer is exposed may be equal to or less than 50 nm.

According to the above-described configuration, the difference in thickness of the piezoelectric-body layer between the region overlapping the electrode and the region where the surface of the piezoelectric-body layer is exposed can be set equal to or less than 50 nm.

An elastic wave device according to a fifteenth aspect of the present disclosure may further include, in any one of the first to fourteenth aspects, a support substrate supporting the piezoelectric-body layer, the electrode, and the cover, the electrode may be made up of electrode fingers, a thickness of the piezoelectric-body layer may be equal to or less than one wavelength determined by a pitch of the electrode fingers, and the piezoelectric-body layer may be configured to excite a plate wave.

According to the above-described configuration, the elastic wave device can be configured to function as an elastic wave device.

An elastic wave device according to a sixteenth aspect of the present disclosure may excite a wave, in any one of the first to fourteenth aspects.

An elastic wave device according to a seventeenth aspect of the present disclosure may excite a bulk wave, in any one of the first to fourteenth aspects.

A communication apparatus according to an eighteenth aspect of the present disclosure may include the elastic wave device according to any one of the first to seventeenth aspects.

A manufacturing method according to a nineteenth aspect of the present disclosure includes steps of: forming a piezoelectric-body layer; forming an electrode on the piezoelectric-body layer; and performing dry etching on the piezoelectric-body layer and the electrode and causing a material separated from the piezoelectric-body layer by the dry etching to adhere to at least a part of a side surface of the electrode.

### Supplementary Note

The invention according to the present disclosure has been described above based on the various drawings and examples. However, the invention according to the present disclosure is not limited to the above-described embodiments. In other words, the invention according to the present disclosure can be modified in various ways within the scope illustrated in the present disclosure, and embodiments obtained by appropriately combining the technical means disclosed in different embodiments are also included in the technical scope of the invention according to the present disclosure. In other words, note that those skilled in the art can easily make various variations or modifications based on the present disclosure. Note that such variations or modifications are included within the scope of the present disclosure.

### REFERENCE SIGNS

1, 100 Elastic wave device
2 Support substrate
3 Piezoelectric-body layer
4 Electrode
5 Cover
6 Multilayer film
6a Low acoustic impedance layer
6b High acoustic impedance layer
7 Protective film
41 First surface
42 Second surface
51 First portion
52 Second portion

1. An elastic wave device comprising:
a piezoelectric-body layer;
an electrode provided on the piezoelectric-body layer; and
a cover covering at least a part of a side surface of the electrode and containing an element constituting the piezoelectric-body layer other than oxygen and nitrogen.

2. The elastic wave device according to claim 1, wherein the piezoelectric-body layer contains lithium tantalate, and the element is lithium or tantalum.

3. The elastic wave device according to claim 1, wherein the piezoelectric-body layer contains lithium niobate, and the element is lithium or niobium.

4. The elastic wave device according to claim 1, wherein the piezoelectric-body layer contains crystal, and the element is silicon.

5. The elastic wave device according to claim 12, wherein the piezoelectric-body layer is made of lithium tantalate, and the cover contains tantalum oxide.

6. The elastic wave device according to claim 1, wherein the piezoelectric-body layer is made of lithium niobate, and the cover contains niobium oxide.

7. The elastic wave device according to claim 1, wherein a density of the cover is larger than a density of the electrode.

8. The elastic wave device according to claim 1, wherein a thickest portion of the cover has a thickness equal to or more than 3 nm.

9. The elastic wave device according to claim 1, wherein the cover comprises a first portion, and a second portion that is located on an upper side of the electrode relative to the first portion and is thinner than the first portion.

10. The elastic wave device according to claim 1, further comprising a protective film covering the piezoelectric-body layer and at least a part of the electrode,
wherein the protective film covers a portion of the electrode near the piezoelectric-body layer via a first portion.

11. The elastic wave device according to claim 1,
wherein a side surface of the electrode comprises a first surface that is not perpendicular to a surface of the piezoelectric-body layer, and
the cover is in contact with the first surface.

12. The elastic wave device according to claim 11,
wherein the side surface of the electrode further comprises a second surface that is located near the surface of the piezoelectric-body layer and is continuous with a first surface,
an angle formed between a direction perpendicular to the surface of the piezoelectric-body layer and the second surface is smaller than an angle formed between the direction perpendicular to the surface of the piezoelectric-body layer and the first surface, and
the cover is in contact with the second surface.

13. The elastic wave device according to claim 1, wherein a thickness of the piezoelectric-body layer in a region of the electrode is larger than a thickness of the piezoelectric-body layer in a region where a surface of the piezoelectric-body layer is exposed.

14. The elastic wave device according to claim 1, wherein a difference in thickness between the region of the electrode and the region where the surface of the piezoelectric-body layer is exposed is equal to or less than 50 nm.

15. The elastic wave device according to claim 1, further comprising a support substrate supporting the piezoelectric-body layer, the electrode, and the cover,
wherein the electrode is made up of electrode fingers,
a thickness of the piezoelectric-body layer is equal to or less than one wavelength determined by a pitch of the electrode fingers, and
the piezoelectric-body layer is configured to excite a plate wave.

16. The elastic wave device according to claim 1, wherein the elastic wave device excites a wave.

17. The elastic wave device according to claim 1, wherein the elastic wave device excites a bulk wave.

18. A communication apparatus comprising the elastic wave device according to claim 1.

19. A manufacturing method comprising:
forming a piezoelectric-body layer;
forming an electrode on the piezoelectric-body layer; and
performing dry etching on the piezoelectric-body layer and the electrode and causing a material separated from the piezoelectric-body layer by the dry etching to adhere to at least a part of a side surface of the electrode.
